(19) United States
(12) Patent Application Publication
(10) Pub. No.: US 2024/0334649 A1
(43) Pub. Date: Oct. 3, 2024

(54) IMMERSION LIQUID COOLING DEVICE

(71) Applicant: Hebei Qinhuai Data Co., Limited., Zhangjiakou City (CN)

(72) Inventors: Binghua ZHANG, Zhangjiakou City (CN); Mingjiang LI, Zhangjiakou City (CN)

(21) Appl. No.: 18/612,414

(22) Filed: Mar. 21, 2024

(30) Foreign Application Priority Data
Mar. 31, 2023 (CN) 202310333703.5

(51) Int. Cl. H05K 7/20

(52) U.S. Cl. CPC H05K 7/203; H05K 7/20309; H05K 7/20318; H05K 7/20809

(57) ABSTRACT

The present disclosure discloses an immersion liquid cooling device, which includes: a box body internally provided with a server immersed in a cooling liquid; an evaporator arranged at an inner side on a top of the box body to absorb heat of the cooling liquid inside the box body; the condenser arranged above the box body to condense the vaporized cooling medium and allow the condensed cooling medium to flow back into the evaporator under gravity; a pressure sensor arranged inside the box body to detect an air pressure inside the box body; a liquid level detector arranged inside the box body to detect a liquid level of the cooling liquid; a temperature sensor arranged inside the box body to detect a temperature inside the box body; and a flow sensor arranged in the condenser to detect a flow rate of the cooling medium entering the condenser.

### CROSS REFERENCE TO RELATED APPLICATION

This application claims priority to Chinese Patent Application No. 202310333703.5, titled “IMMERSION LIQUID COOLING DEVICE” and filed to the China National Intellectual Property Administration on Mar. 31, 2023, the entire contents of which are incorporated herein by reference.

### TECHNICAL FIELD

The present disclosure relates to the field of data centers, and more particularly, to an immersion liquid cooling device.

### BACKGROUND

With the significant increase of chip computing power, chip power consumption and heat dissipation demands are increasing, liquid cooling systems are gradually becoming a choice for new-generation data center cooling systems.

At present, immersion liquid cooling technologies are commonly employed to completely immerse servers into a box body containing insulating liquids. The servers transfer heat to the insulating liquids, and then the heated insulating liquids are pumped from the box body to an intermediate heat exchanger for cooling through a fluid pump. Finally, the insulating liquids are transported back to the box body to achieve cooling of the servers. The heat from the intermediate heat exchanger is discharged into air through cooling water on other side of the intermediate heat exchanger, where a cooling water pump is connected to an outdoor cooling device.

In the above cooling solutions, the cooling system requires the use of various devices such as the fluid pump, the cooling water pump, and the outdoor cooling device. Thus, the cooling system is complex in structural design, poor in stability, lower in reliability, and higher in power consumption.

### SUMMARY

Objectives of the present disclosure are to provide an immersion liquid cooling device, which is simple in structural design, stable and reliable in operation, and low in power consumption.

Embodiments of the present disclosure provide an immersion liquid cooling device, which includes:
a box body internally provided with a server immersed in a cooling liquid;
an evaporator arranged at an inner side on a top of the box body to absorb heat of the cooling liquid inside the box body, such that a cooling medium inside the evaporator is vaporized, and the vaporized cooling medium enters a condenser;
the condenser arranged above the box body to condense the vaporized cooling medium and allow the condensed cooling medium to flow back into the evaporator under gravity;
a pressure sensor arranged inside the box body to detect an air pressure inside the box body;
a liquid level detector arranged inside the box body to detect a liquid level of the cooling liquid;
a temperature sensor arranged inside the box body to detect a temperature inside the box body; and
a flow sensor arranged in the condenser to detect a flow rate of the cooling medium entering the condenser.

Alternatively, a flow direction of the cooling medium during vaporization is clockwise from bottom to top, and a flow direction of the condensed cooling medium is clockwise from top to bottom.

Alternatively, the evaporator includes one of:
a heat pipe evaporator and a heat exchanger.

Alternatively, the heat exchanger includes:
a copper coil heat exchanger, a cold plate heat exchanger, a plate heat exchanger,
or a shell-and-tube heat exchanger.

Alternatively, the condenser includes:
a water-cooled condenser or an air-cooled condenser.

Alternatively, number of the evaporators is a target number.

Alternatively, number of the condensers is a target number.

Alternatively, a set of partition boards are arranged inside the box body to divide interior of the box body into a plurality of independent accommodation spaces, and each of the plurality of accommodation spaces is provided with a through hole for interconnection.

Alternatively, a size of the box body in an extension direction is not greater than a target multiple of a size of the box body in a height direction.

Alternatively, the size of the box body in the extension direction is not greater than half of the size of the box body in the height direction.

In the above technical solutions, the immersion liquid cooling device includes a box body, an evaporator, and a condenser. The evaporator is arranged at an inner side on a top of the box body to absorb heat of the cooling liquid inside the box body, such that a cooling medium inside the evaporator is vaporized, and the vaporized cooling medium enters the condenser. The condenser can condense the vaporized cooling medium and allow the condensed cooling medium to flow back into the evaporator under gravity, thereby achieving an objective of releasing heat from the server. In this way, there is no need to additionally provide devices such as fluid pumps, cooling water pumps, and outdoor cooling devices. Thus, structural design is simple, and operating efficiency and reliability of the immersion liquid cooling device are improved. In addition, compared to liquid cooling devices adopting the fluid pumps, the immersion liquid cooling device has lower power consumption, which reduces costs of the immersion liquid cooling device. Furthermore, the immersion liquid cooling device is suitable for edge computing. Moreover, the immersion liquid cooling device is provided with a pressure sensor, a liquid level sensor, a temperature sensor, and a flow sensor, to achieve real-time detection of the immersion liquid cooling device. In this way, safe operation of the immersion liquid cooling device is ensured, and cooling effects of the immersion liquid cooling device are improved.

### BRIEF DESCRIPTION OF THE DRAWINGS

To describe the technical solutions of the embodiments of the present disclosure more clearly, the accompanying drawings required for describing the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a schematic diagram of an immersion liquid cooling device provided in an embodiment of the present disclosure;

FIG. 2 is a schematic diagram of a box body provided in an embodiment of the present disclosure; and

FIG. 3 is another schematic diagram of the immersion liquid cooling device provided in an embodiment of the present disclosure.

### REFERENCE NUMERALS IN THE ACCOMPANYING DRAWINGS

box body 10; evaporator 20; water-cooled condenser 30; air-cooled condenser 40; and immersion liquid cooling device 100.

### DETAILED DESCRIPTION

Detailed description of the embodiments of the present disclosure will further be made below with reference to the accompanying drawings to make the objectives, technical solutions and advantages of the present disclosure more apparent.

An immersion liquid cooling device generally is comprised of a box body, an evaporator, and a condenser. In the box body there is a cooling liquid, into which a server is immersed, such that the server transfers heat to the cooling liquid. The evaporator is arranged at an inner side on a top of the box body to absorb the heat of the cooling liquid, such that a cooling medium inside the evaporator is vaporized, and the vaporized cooling medium enters the condenser. The condenser is configured to condense the cooling medium, release the heat, and allow the cooled cooling medium to flow back into the evaporator under gravity.

The currently used box body needs a fluid pump to connect one side of a heat exchanger, and other side of the heat exchanger needs to be connected to a cooling water pump and an outdoor cooling device to discharge the heat into air. On this basis, the present disclosure designs an immersion liquid cooling device, which can operate without the fluid pump, the cooling water pump, or the outdoor cooling device. The immersion liquid cooling device of the present disclosure will be described in detail below in conjunction with specific embodiments.

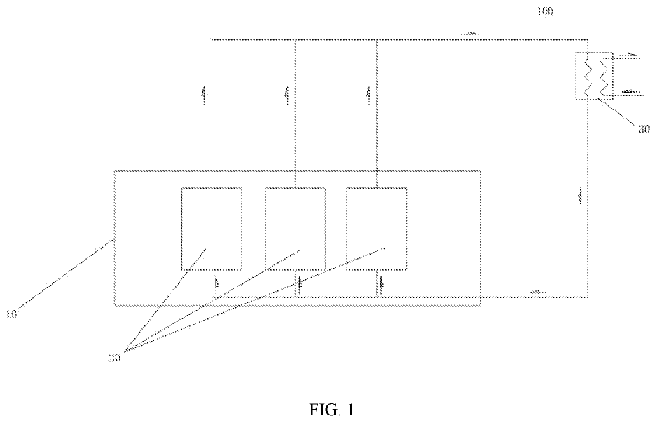

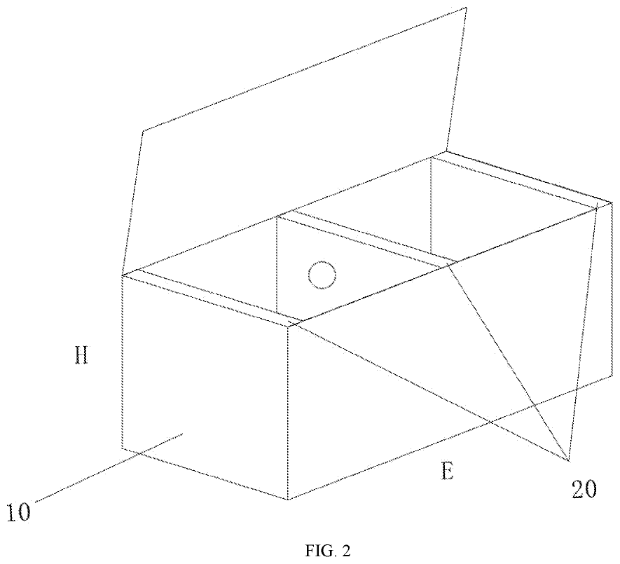

The embodiments of the present disclosure provide an immersion liquid cooling device 100. FIG. 1 is a block diagram of the immersion liquid cooling device 100 provided in the embodiments of the present disclosure. As shown in FIG. 1 and FIG. 2, the immersion liquid cooling device 100 includes:
a box body 10 internally provided with a server immersed in a cooling liquid;
an evaporator 20 arranged at an inner side on a top of the box body 10 to absorb heat of the cooling liquid inside the box body 10, such that a cooling medium inside the evaporator 20 is vaporized, and the vaporized cooling medium enters a condenser;
the condenser arranged above the box body 10 to condense the vaporized cooling medium and allow the condensed cooling medium to flow back into the evaporator 20 under gravity;
a pressure sensor arranged inside the box body 10 to detect an air pressure inside the box body 10;
a liquid level detector arranged inside the box body 10 to detect a liquid level of the cooling liquid;
a temperature sensor arranged inside the box body 10 to detect a temperature inside the box body 10; and
a flow sensor arranged in the condenser to detect a flow rate of the cooling medium entering the condenser.

The cooling liquid may be an insulation cooling liquid, such as Fluorinert or mineral oil. The server is immersed in the cooling liquid, which is used for quickly absorbing heat generated by the server, thereby transferring the heat generated by the server to the evaporator 20. The evaporator 20 is arranged at an inner side on a top of the box body 10. The evaporator 20 is configured to absorb heat transferred by the cooling liquid, such that the heat transferred by the cooling liquid is evenly dissipated on the evaporator 20. The cooling medium inside the evaporator 20 absorbs the heat transferred by the cooling liquid and is vaporized, and the vaporized cooling medium enters the condenser. The condenser may be an air-cooled condenser 40 or a water-cooled condenser 30. The condenser is configured to condense the vaporized cooling medium, release the heat, and allow the condensed cooling medium to flow back into the evaporator 20 under gravity for cyclic heat exchange, thereby achieving the objective of releasing the heat from the server for cyclic heat exchange.

The pressure sensor may be a capacitive pressure sensor, which may be arranged inside the box body 10 and next to the evaporator 20 to detect gas pressure inside the box body 10. For example, the pressure sensor can detect the pressure of the vaporized cooling liquid to prevent from adversely affecting operation safety of the immersion liquid cooling device 100 due to higher pressure inside the box body 10. The liquid level sensor may be a photoelectric liquid level sensor, and may be arranged in the cooling liquid inside the box body 10 to detect the liquid level of the cooling liquid inside the box body 10, such that a corresponding capacity of the cooling liquid is flexibly allocated according to number of the servers, thereby improving cooling effects of the immersion liquid cooling device 100. The temperature sensor may be arranged inside the box body 10 and next to the evaporator 20 to detect the temperature inside the box body 10, to prevent from adversely affecting the operation safety of the immersion liquid cooling device 100 due to higher temperature inside the box body 10. The flow sensor may be arranged in the condenser to accurately detect the flow rate of the cooling medium entering the condenser.

In the above technical solutions, the immersion liquid cooling device includes a box body, an evaporator, and a condenser. The evaporator is arranged at an inner side on a top of the box body to absorb heat of the cooling liquid inside the box body, such that a cooling medium inside the evaporator is vaporized, and the vaporized cooling medium enters the condenser. The condenser can condense the vaporized cooling medium and allow the condensed cooling medium to flow back into the evaporator under gravity, thereby achieving an objective of releasing heat from the server. In this way, there is no need to additionally provide devices such as fluid pumps, cooling water pumps, and outdoor cooling devices. Thus, structural design is simple, and operating efficiency and reliability of the immersion liquid cooling device are improved. In addition, compared to immersion liquid cooling devices adopting the fluid pumps, this immersion liquid cooling device has lower power consumption, which reduces costs of this immersion liquid cooling device. Furthermore, the immersion liquid cooling device is suitable for edge computing. Moreover, the immersion liquid cooling device is provided with a pressure sensor, a liquid level sensor, a temperature sensor, and a flow sensor, to achieve real-time detection of the immersion liquid cooling device. In this way, safe operation of the immersion liquid cooling device is ensured, and cooling effects of the immersion liquid cooling device are improved.

In one possible embodiment, a flow direction of the cooling medium during vaporization is clockwise from bottom to top, and a flow direction of the condensed cooling medium is clockwise from top to bottom.

The cooling medium may include fluorocarbons, hydrocarbons, and organosilicon compounds. This type of cooling medium is lower in boiling point and is easier for vaporization. The evaporator 20 absorbs the heat of the cooling liquid inside box body 10, such that portion of the liquid cooling medium inside the evaporator 20 to absorbs the heat and is vaporized, thus becoming a gaseous cooling medium. Compared to the liquid cooling medium, the gaseous cooling medium has higher temperature, lower density, and greater buoyancy. Therefore, the gaseous cooling medium will float up and enter the condenser. As shown in FIG. 1, the flow direction of the cooling medium during vaporization is clockwise from bottom to top, such that the cooling medium may enter the condenser, thereby achieving the objective of releasing the heat from the server, and thus improving the operating efficiency and reliability of the immersion liquid cooling device 100.

The gaseous cooling medium is transformed into the liquid cooling medium by the condenser, thereby releasing the heat. As shown in FIG. 2, a height of the condenser is greater than that of the box body 10. Under gravity, the liquid cooling medium will flow back into the evaporator 20 for cyclic heat exchange. As shown in FIG. 2, the flow direction of the condensed cooling medium is clockwise from top to bottom, such that the cooled cooling medium flows back into the evaporator 20, thereby achieving the objective of releasing the heat from the server, and thus improving the operating efficiency and reliability of the immersion liquid cooling device 100.

In a possible embodiment, the evaporator 20 includes one of:
a heat pipe evaporator and a heat exchanger.

The heat pipe evaporator is a device where one end is an evaporation section and other end is a condensation section, and heat is transferred from the evaporation section to the condensation section. The heat exchanger is a device that transfers heat from a hot fluid to a cold fluid. The heat exchanger may include a copper coil heat exchanger, a cold plate heat exchanger, a plate heat exchanger, or a shell-and-tube heat exchanger.

The copper coil heat exchanger is a type of heat exchanger that uses copper core coils to maximize a heat exchange area in a smaller space. The cold plate heat exchanger is a device that transfers heat through a capillary tube. The plate heat exchanger is comprised of many corrugated sheets arranged at certain intervals, and the fluid flows in a channel for heat exchange through the sheets. The shell-and-tube heat exchanger may have a cylindrical shell internally provided with a tube bundle, where two ends of the tube bundle are fixed on a tube sheet, and the fluid flows inside the tube bundle for heat exchange.

Taking the plate heat exchanger as an example, when the heat transferred by the cooling liquid reaches the plate heat exchanger, the fluid inside the plate heat exchanger flows and exchanges heat to rapidly diffuse the heat, such that the liquid cooling medium on the plate heat exchanger absorbs the heat and is vaporized. The vaporized cooling medium flows upwards into the condenser.

Therefore, by means of any one of the aforementioned evaporators 20, the heat of the cooling liquid inside the box body 10 may be absorbed to evenly dissipate the heat in the evaporator 20, thereby ensuring efficient heat exchange in the evaporator 20. Next, the cooling medium inside the evaporator 20 is vaporized, and the vaporized cooling medium enters the condenser, thereby achieving the objective of releasing the heat from the server, and thus improving the operating efficiency and reliability of the immersion liquid cooling device 100. In a possible embodiment, the condenser may include:
a water-cooled condenser 30 or an air-cooled condenser 40.

Different condensers have different media and have different treatment methods for different cooling media. As shown in FIG. 1, the condenser is the water-cooled condenser 30, and the medium of the water-cooled condenser 30 is water. The cooling medium inside the evaporator 20 is vaporized, and the vaporized cooling medium enters the water-cooled condenser 30. After passing through the water-cooled condenser 30, the gaseous cooling medium exchanges heat with the cold water in the water-cooled condenser 30, such that the gaseous cooling medium is condensed into the liquid cooling medium, thus releasing the heat.

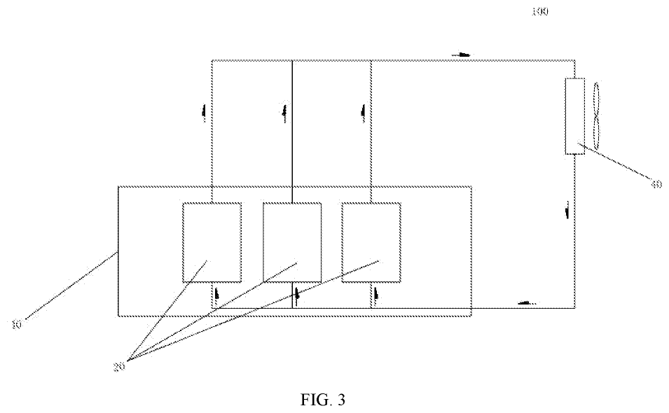

As shown in FIG. 3, the condenser is the air-cooled condenser 40, and the cooling medium of the air-cooled condenser 40 is air. The cooling medium inside the evaporator 20 is vaporized, and the vaporized cooling medium enters the air-cooled condenser 40. After passing through the air-cooled condenser 40, the gaseous cooling medium exchanges heat with the air in the air-cooled condenser 40, such that the gaseous cooling medium is condensed into the liquid cooling medium, thus releasing the heat. In this way, the operating efficiency and reliability of the immersion liquid cooling device 100 are improved.

In a possible embodiment, number of the evaporators 20 is a target number.

As shown in FIG. 1, the number of the evaporators 20 may be three or other number such as six, such that the heat dissipation needs of the server may be met, a heat dissipation rate of the server may be increased, and the operating efficiency and reliability of the immersion liquid cooling device 100 may be improved.

In a possible embodiment, number of the condensers is a target number.

For example, the number of the condensers may be one or more. As shown in FIG. 1, one box body 10, a plurality of evaporators 20, and one condenser may constitute one immersion liquid cooling device 100. A plurality of box bodies 10, a plurality of evaporators 20, and a plurality of condensers may constitute a plurality of immersion liquid cooling devices 100. In this way, heat dissipation of a plurality of servers is achieved, heat dissipation efficiency of the servers is accelerated, and the operating efficiency and reliability of the immersion liquid cooling device 100 are improved.

In a possible embodiment, a set of partition boards are arranged inside the box body 10 to divide interior of the box body 10 into a plurality of independent accommodation spaces, and each of the plurality of accommodation spaces is provided with a through hole for interconnection.

As shown in FIG. 2, a set of partition boards may be arranged inside the box body 10, or a plurality of sets of partition boards may be arranged inside the box body 10, such that interior of the box body 10 may be divided into a plurality of independent accommodation spaces, and one or more servers (cabinets) are immersed into each of the plurality of accommodation spaces. The heat of the cooling liquid in each of the plurality of accommodation spaces is transmitted upwards to the evaporator 20, and heat transmitted to the accommodation space at a lateral side is reduced, to accelerate the heat dissipation efficiency of the server.

In a possible embodiment, a size of the box body in an extension direction is not greater than a target multiple of a size of the box body in a height direction.

As shown in FIG. 2, the extension direction refers to a direction of a length (represented by E) of the immersion liquid cooling device, and the size in the height direction refers to a direction of a height (represented by H) of the immersion liquid cooling device. The size of the box body in the extension direction is not greater than the target multiple of the size of the box body in the height direction. For example, the size of the immersion liquid cooling device in the extension direction is not greater than half of the size of the immersion liquid cooling device in the height direction.

Typically, specifications of the servers include 1U, 2U, etc. Sizes of the servers may be multiple of 48.26 centimeters in width and 4.445 centimeters in height. In this way, by limiting the sizes of the box body in the extension direction and height direction, the box body 10 can accommodate a plurality of servers (or cabinets), thereby meeting the heat dissipation needs of the servers.

Other embodiments of the present disclosure will be apparent to those skilled in the art from consideration of the specification and practice of the invention disclosed here. The present disclosure is intended to cover any variations, uses, or adaptations of the present disclosure following the general principles thereof and including such departures from the present disclosure as come within known or customary practice in the art. It is intended that the specification and embodiments be considered as exemplary only, with a true scope and spirit of the present disclosure being indicated by the following claims.

It will be appreciated that the present disclosure is not limited to the exact construction that has been described above and illustrated in the accompanying drawings, and that various modifications and changes can be made without departing from the scope thereof. It is intended that the scope of the present disclosure only be limited by the appended claims.

What is claimed is:

1. An immersion liquid cooling device comprising:
a box body internally provided with a server immersed in a cooling liquid;
an evaporator arranged at an inner side on a top of the box body to absorb heat of the cooling liquid inside the box body, such that a cooling medium inside the evaporator is vaporized, and the vaporized cooling medium enters a condenser;
the condenser arranged above the box body to condense the vaporized cooling medium and allow the condensed cooling medium to flow back into the evaporator under gravity;
a pressure sensor arranged inside the box body to detect an air pressure inside the box body;
a liquid level detector arranged inside the box body to detect a liquid level of the cooling liquid;
a temperature sensor arranged inside the box body to detect a temperature inside the box body; and
a flow sensor arranged in the condenser to detect a flow rate of the cooling medium entering the condenser.

2. The liquid cooling device according to claim 1, wherein a flow direction of the cooling medium during vaporization is clockwise from bottom to top, and a flow direction of the condensed cooling medium is clockwise from top to bottom.

3. The liquid cooling device according to claim 1, wherein the evaporator comprises one of:
a heat pipe evaporator and a heat exchanger.

4. The liquid cooling device according to claim 3, wherein the heat exchanger comprises:
a copper coil heat exchanger, a cold plate heat exchanger, a plate heat exchanger, or a shell-and-tube heat exchanger.

5. The liquid cooling device according to claim 1, wherein the condenser comprises:
a water-cooled condenser or an air-cooled condenser.

6. The liquid cooling device according to claim 1, wherein number of the evaporators is a target number.

7. The liquid cooling device according to claim 1, wherein number of the condensers is a target number.

8. The liquid cooling device according to claim 1, wherein a set of partition boards are arranged inside the box body to divide interior of the box body into a plurality of independent accommodation spaces, and each of the plurality of accommodation spaces is provided with a through hole for interconnection.

9. The liquid cooling device according to claim 1, wherein a size of the box body in an extension direction is not greater than a target multiple of a size of the box body in a height direction.

10. The liquid cooling device according to claim 9, wherein the size of the box body in the extension direction is not greater than half of the size of the box body in the height direction.
